(19) United States
(12) Patent Application Publication
(10) Pub. No.: US 2025/0250714 A1
(43) Pub. Date: Aug. 7, 2025

(54) VAPOR PHASE GROWTH APPARATUS AND VAPOR PHASE GROWTH METHOD

(71) Applicant: NuFlare Technology, Inc., Kanagawa (JP)

(72) Inventors: Keisuke KURASHIMA, Yokohama-shi (JP); Yuya TAKADA, Kyoto-shi (JP)

(21) Appl. No.: 19/039,485

(22) Filed: Jan. 28, 2025

(30) Foreign Application Priority Data
Feb. 7, 2024 (JP) 2024-017526

(51) Int. Cl. C30B 25/08; C30B 25/12; C30B 25/16; C30B 29/36

(52) U.S. Cl. CPC C30B 25/08; C30B 25/12; C30B 25/165; C30B 29/36

(57) ABSTRACT

A vapor phase growth apparatus according to embodiments includes: a reactor; a holder placing a substrate; a source gas flow path supplying a first source gas containing silicon and chlorine; a purge gas flow path supplying a purge gas containing chlorine and hydrogen; and a control unit controlling supply of the first source gas and the purge gas. The control unit controls the ratio of the sum of a second amount of substance being the amount of substance of chlorine in the first source gas, and a third amount of substance being the amount of substance of chlorine in the purge gas, to a first amount of substance being the amount of substance of silicon in the first source gas, to be 30 or more in a first period. The control unit increases a flow rate of the first source gas in a second period after the first period.

### CROSS-REFERENCE TO RELATED APPLICATION

This application is based upon and claims the benefit of priority from Japanese Patent Applications No. 2024-017526, filed on Feb. 7, 2024, the entire contents of which are incorporated herein by reference.

### FIELD OF THE INVENTION

Embodiments relate to a vapor phase growth apparatus and a vapor phase growth method for forming a film by supplying a gas to a substrate.

### BACKGROUND OF THE INVENTION

As a method of forming a high-quality semiconductor film, there is an epitaxial growth technique forming a single crystal film on the surface of a substrate by vapor phase growth. In a vapor phase growth apparatus using the epitaxial growth technique, a substrate is placed on a holder in a reactor held at atmospheric pressure or reduced pressure.

Then, while heating the substrate, a process gas containing the raw material of a film is supplied to the reactor through a gas introduction unit above the reactor.

A thermal reaction of the process gas occurs on the surface of the substrate, and an epitaxial single crystal film is formed on the surface of the substrate.

Defects may occur on the surface of the formed epitaxial single crystal film. The defects are, for example, pits or bumps.

### SUMMARY OF THE INVENTION

A vapor phase growth apparatus according to an aspect of embodiments includes: a reactor; a holder provided in the reactor, a substrate being placed on the holder; a source gas flow path supplying a first source gas containing silicon and chlorine into the reactor; a purge gas flow path supplying a purge gas containing chlorine and hydrogen into the reactor; and a control unit controlling supply of the first source gas and the purge gas into the reactor. The control unit controls a ratio ((second amount of substance+third amount of substance)/first amount of substance) of a sum of a second amount of substance as an amount of substance of chlorine contained in the first source gas supplied to the reactor per unit time and a third amount of substance as an amount of substance of chlorine contained in the purge gas supplied to the reactor per unit time to a first amount of substance as an amount of substance of silicon contained in the first source gas supplied to the reactor per unit time to be 30 or more in a first period. The control unit controls a flow rate of the first source gas to increase in a second period after the first period.

A vapor phase growth method according to an aspect of embodiments is a vapor phase growth method for forming a silicon carbide film on a substrate placed on a holder provided in a reactor, and includes: supplying a first source gas containing silicon and chlorine and a purge gas containing chlorine and hydrogen into the reactor so that a ratio ((second amount of substance+third amount of substance)/first amount of substance) of a sum of a second amount of substance as an amount of substance of chlorine contained in the first source gas supplied to the reactor per unit time and a third amount of substance as an amount of substance of chlorine contained in the purge gas supplied to the reactor per unit time to a first amount of substance as an amount of substance of silicon contained in the first source gas supplied to the reactor per unit time is 30 or more in a first period; and increasing a flow rate of the first source gas supplied into the reactor in a second period after the first period.

### BRIEF DESCRIPTION OF THE DRAWINGS

FIG. 1 is a schematic cross-sectional view of a vapor phase growth apparatus according to a first embodiment;

FIG. 2 is an enlarged schematic cross-sectional view of a part of a gas introduction unit in the vapor phase growth apparatus according to the first embodiment;

FIG. 3 is an enlarged schematic cross-sectional view of a part of a gas introduction unit in the vapor phase growth apparatus according to the first embodiment;

FIG. 4 is an explanatory diagram of control by a control circuit in the vapor phase growth apparatus according to the first embodiment;

FIG. 5 is an explanatory diagram of control by a control circuit in the vapor phase growth apparatus according to the first embodiment;

FIG. 6 is an explanatory diagram of control by a control circuit in the vapor phase growth apparatus according to the first embodiment;

FIGS. 7A and 7B are explanatory diagrams of the function and effect of the vapor phase growth apparatus and a vapor phase growth method according to the first embodiment;

FIG. 8 is an explanatory diagram of the function and effect of the vapor phase growth apparatus and the vapor phase growth method according to the first embodiment;

FIG. 9 is an explanatory diagram of the vapor phase growth apparatus and the vapor phase growth method according to the first embodiment;

FIG. 10 is an explanatory diagram of the vapor phase growth apparatus and the vapor phase growth method according to the first embodiment;

FIG. 11 is an explanatory diagram of the vapor phase growth apparatus and the vapor phase growth method according to the first embodiment;

FIG. 12 is a schematic cross-sectional view of a vapor phase growth apparatus according to a second embodiment;

FIG. 13 is an explanatory diagram of control by a control circuit in the vapor phase growth apparatus according to the second embodiment;

FIG. 14 is an explanatory diagram of control by a control circuit in the vapor phase growth apparatus according to the second embodiment; and

FIG. 15 is an explanatory diagram of control by a control circuit in the vapor phase growth apparatus according to the second embodiment.

### DETAILED DESCRIPTION OF THE EMBODIMENTS

Hereinafter, embodiments will be described with reference to the diagrams.

In this specification, the same or similar members may be denoted by the same reference numerals.

In this specification, the direction of gravity in a state in which a vapor phase growth apparatus is installed so that a film can be formed is defined as “down”, and the opposite direction is defined as “up”. Therefore, “lower” means a position in the direction of gravity with respect to the reference, and “downward” means the direction of gravity with respect to the reference. Then, “upper” means a position in a direction opposite to the direction of gravity with respect to the reference, and “upward” means a direction opposite to the direction of gravity with respect to the reference. In addition, the “vertical direction” is the direction of gravity.

In addition, in this specification, “process gas” is a general term for gases used for forming a film, and is a concept including, for example, a source gas, an assist gas, a dopant gas, a carrier gas, a purge gas, and a mixed gas thereof.

### First Embodiment

A vapor phase growth apparatus according to a first embodiment includes: a reactor; a holder provided in the reactor, a substrate being placed on the holder; a source gas flow path for supplying a first source gas containing silicon and chlorine into the reactor; a purge gas flow path for supplying a purge gas containing chlorine and hydrogen into the reactor; and a control unit for controlling supply of the first source gas and the purge gas into the reactor. The control unit controls a ratio ((second amount of substance+third amount of substance)/first amount of substance) of a sum of a second amount of substance as an amount of substance of chlorine contained in the first source gas supplied to the reactor per unit time and a third amount of substance as an amount of substance of chlorine contained in the purge gas supplied to the reactor per unit time to a first amount of substance as an amount of substance of silicon contained in the first source gas supplied to the reactor per unit time to be 30 or more in a first period. The control unit controls a flow rate of the first source gas to increase in a second period after the first period.

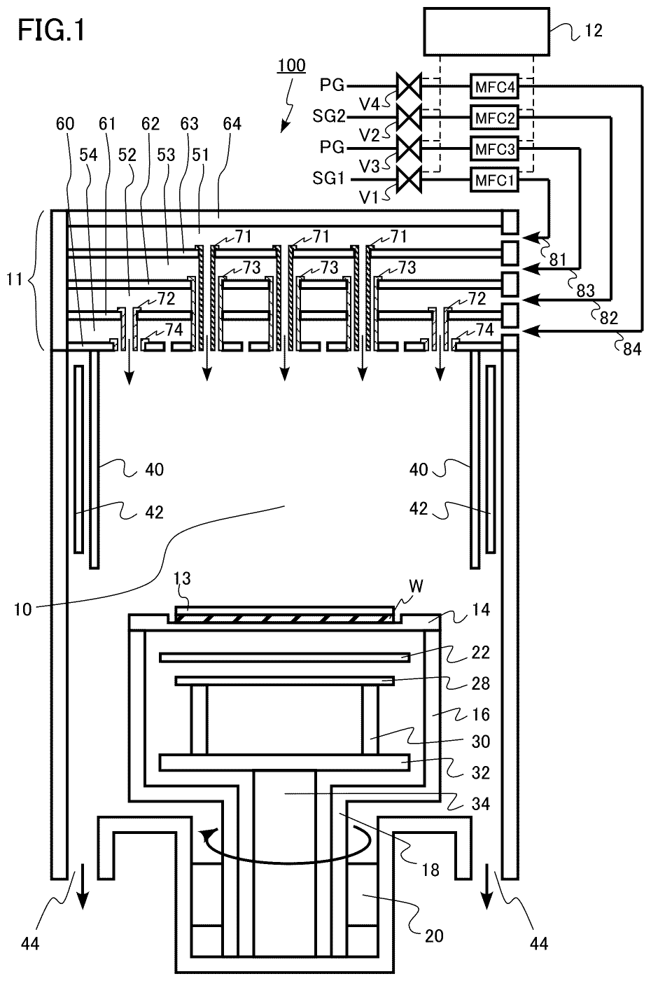

FIG. 1 is a schematic cross-sectional view of the vapor phase growth apparatus according to the first embodiment. A vapor phase growth apparatus 100 according to the first embodiment is, for example, a single wafer type epitaxial growth apparatus for epitaxially growing a single crystal silicon carbide film (SiC film) on a single crystal silicon carbide substrate (SiC substrate). The vapor phase growth apparatus 100 according to the first embodiment is a vertical vapor phase growth apparatus in which a process gas is supplied in a vertical direction to the surface of the SiC substrate.

The vapor phase growth apparatus 100 according to the first embodiment includes a reactor 10, a gas introduction unit 11, and a control circuit 12 (control unit). The reactor 10 includes a susceptor 14 (holder), a rotating body 16, a rotating shaft 18, a rotation driving mechanism 20, a first heater 22, a reflector 28, a support column 30, a fixing table 32, a fixing shaft 34, a hood 40, a second heater 42, and a gas exhaust port 44. The gas introduction unit 11 includes a first source gas region 51, a second source gas region 52, a first purge gas region 53, a second purge gas region 54, a rectifying plate 60, partition plates 61, 62, 63, a top plate 64, a first source gas conduit 71, a second source gas conduit 72, a first purge gas conduit 73, and a second purge gas conduit 74.

The vapor phase growth apparatus 100 according to the first embodiment includes a first source gas supply pipe 81, a second source gas supply pipe 82, a first purge gas supply pipe 83, a second purge gas supply pipe 84, a first mass flow controller MFC1, a second mass flow controller MFC2, a third mass flow controller MFC3, a fourth mass flow controller MFC4, a first valve V1, a second valve V2, a third valve V3, and a fourth valve V4.

The first source gas supply pipe 81, the first source gas region 51, and the first source gas conduit 71 form a first source gas flow path. The first source gas flow path supplies a first source gas SG1 to the reactor 10.

The second source gas supply pipe 82, the second source gas region 52, and the second source gas conduit 72 form a second source gas flow path. The second source gas flow path supplies a second source gas SG2 to the reactor 10.

The first source gas flow path and the second source gas flow path are examples of a source gas flow path.

The first purge gas supply pipe 83, the first purge gas region 53, and the first purge gas conduit 73 form a first purge gas flow path. The second purge gas supply pipe 84, the second purge gas region 54, and the second purge gas conduit 74 form a second purge gas flow path.

The first purge gas flow path and the second purge gas flow path supply a purge gas PG to the reactor 10. The first purge gas flow path and the second purge gas flow path are examples of a purge gas flow path.

The first valve V1 and the first mass flow controller MFC1 are provided in the first source gas supply pipe 81. The first valve V1 has a function of switching between starting and stopping the introduction of the first source gas SG1 introduced into the first source gas supply pipe 81. The first mass flow controller MFC1 has a function of adjusting the flow rate of the first source gas SG1 introduced into the first source gas supply pipe 81 to a predetermined amount.

The second valve V2 and the second mass flow controller MFC2 are provided in the second source gas supply pipe 82. The second valve V2 has a function of switching between starting and stopping the introduction of the second source gas SG2 introduced into the second source gas supply pipe 82. The second mass flow controller MFC2 has a function of adjusting the flow rate of the second source gas SG2 introduced into the second source gas supply pipe 82 to a predetermined amount.

The third valve V3 and the third mass flow controller MFC3 are provided in the first purge gas supply pipe 83. The third valve V3 has a function of switching between starting and stopping the introduction of the purge gas PG introduced into the first purge gas supply pipe 83. The third mass flow controller MFC3 has a function of adjusting the flow rate of the purge gas PG introduced into the first purge gas supply pipe 83 to a predetermined amount.

The fourth valve V4 and the fourth mass flow controller MFC4 are provided in the second purge gas supply pipe 84. The fourth valve V4 has a function of switching between starting and stopping the introduction of the purge gas PG introduced into the second purge gas supply pipe 84.

The fourth mass flow controller MFC4 has a function of adjusting the flow rate of the purge gas PG introduced into the second purge gas supply pipe 84 to a predetermined amount.

The first valve V1, the second valve V2, the third valve V3, the fourth valve V4, the first mass flow controller MFC1, the second mass flow controller MFC2, the third mass flow controller MFC3, and the fourth mass flow controller MFC4 are controlled by the control circuit 12. The reactor 10 is formed of, for example, stainless

steel. The reactor 10 has a cylindrical wall. In the reactor 10, an SiC film is formed on a wafer W. The wafer W is an example of a substrate.

The susceptor 14 is provided in the reactor 10. The wafer W can be placed on the susceptor 14. An opening may be provided at the center of the susceptor 14. The susceptor 14 is an example of a holder.

The susceptor 14 is formed of, for example, a highly heat-resistant material, such as SiC, carbon, or carbon coated with SiC or TaC.

The susceptor 14 is fixed to the upper part of the rotating body 16. The rotating body 16 is fixed to the rotating shaft 18. The susceptor 14 is indirectly fixed to the rotating shaft 18.

The rotating shaft 18 can be rotated by the rotation driving mechanism 20. By rotating the rotating shaft 18 using the rotation driving mechanism 20, it is possible to rotate the susceptor 14. By rotating the susceptor 14, it is possible to rotate the wafer W placed on the susceptor 14.

With the rotation driving mechanism 20, for example, the wafer W can be rotated at a rotation speed of 300 rpm or more and 3000 rpm or less. The rotation driving mechanism 20 is formed by, for example, a motor and a bearing.

The first heater 22 is provided below the susceptor 14. The first heater 22 is provided in the rotating body 16. The first heater 22 heats the wafer W held by the susceptor 14 from below. The first heater 22 is, for example, a resistance heater. The first heater 22 has, for example, a disc shape with a comb-shaped pattern. In addition, the first heater 22 may be divided into an outer heater (not shown) for heating the outer periphery of the wafer and an inner heater (not shown) for heating the inner periphery of the wafer.

The reflector 28 is provided below the first heater 22. The first heater 22 is provided between the reflector 28 and the susceptor 14.

The reflector 28 reflects the heat radiated downward from the first heater 22 to improve the heating efficiency of the wafer W. In addition, the reflector 28 prevents the members below the reflector 28 from being heated. The reflector 28 has, for example, a disk shape. The reflector 28 is formed of, for example, a highly heat-resistant material such as SiC-coated carbon.

The reflector 28 is fixed to the fixing table 32 by, for example, a plurality of support columns 30. The fixing table 32 is supported by, for example, the fixing shaft 34.

In order to attach and detach the susceptor 14 to and from the rotating body 16, a push up pin (not shown) is provided in the rotating body 16. The push up pin penetrates, for example, the reflector 28 and the first heater 22.

The second heater 42 is provided between the hood 40 and the inner wall of the reactor 10. The second heater 42 heats the wafer W held by the susceptor 14 from above. By heating the wafer W with the second heater 42 in addition to the first heater 22, it is possible to heat the wafer W to a temperature required for the growth of the SiC film, for example, a temperature of 1500° C. or higher. The second heater 42 is, for example, a resistance heater.

The hood 40 has, for example, a cylindrical shape. The hood 40 has a function of preventing the process gas from coming into contact with the second heater 42. The hood 40 is formed of, for example, a material having high heat resistance such as SiC-coated carbon.

The gas exhaust port 44 is provided at the bottom of the reactor 10. The gas exhaust port 44 discharges a surplus reaction product after the source gas reacts on the surface of the wafer W and a surplus process gas to the outside of the reactor 10. The gas exhaust port 44 is connected to, for example, a vacuum pump (not shown).

In addition, a wafer inlet/outlet and a gate valve (not shown) are provided in the reactor 10. The wafer W can be loaded into the reactor 10 or unloaded to the outside of the reactor 10 through the wafer inlet/outlet and the gate valve.

The gas introduction unit 11 is provided above the reactor 10.

The first source gas SG1 is introduced into the first source gas region 51 from the first source gas supply pipe 81. The first source gas region 51 is provided between the first purge gas region 53 and the top plate 64.

The second source gas SG2 is introduced into the second source gas region 52 from the second source gas supply pipe 82. The second source gas region 52 is provided between the second purge gas region 54 and the first purge gas region 53.

The purge gas PG is introduced into the first purge gas region 53 from the first purge gas supply pipe 83. The first purge gas region 53 is provided between the second source gas region 52 and the first source gas region 51.

The purge gas PG is introduced into the second purge gas region 54 from the second purge gas supply pipe 84. The second purge gas region 54 is provided between the second source gas region 52 and the reactor 10.

The rectifying plate 60 is provided between the reactor 10 and the second purge gas region 54. The rectifying plate 60 has a plurality of holes 60a and a plurality of holes 60b.

The partition plate 61 is provided between the second purge gas region 54 and the second source gas region 52. The partition plate 61 has a plurality of holes 61a.

The partition plate 62 is provided between the second source gas region 52 and the first purge gas region 53. The partition plate 62 has a plurality of holes 62a.

The partition plate 63 is provided between the first purge gas region 53 and the first source gas region 51. The partition plate 63 has a hole 63a.

The top plate 64 is provided above the first source gas region 51.

The first source gas SG1 is a silicon (Si) source gas. The first source gas SG1 contains silicon (Si) and chlorine (Cl). The first source gas SG1 contains, for example, silane (SiH₄) or silane chloride (SiH₄₋ₙClₙ:n=1 to 4). The first source gas SG1 contains, for example, hydrogen chloride (HCl). The first source gas SG1 contains, for example, hydrogen gas (H₂). The first source gas SG1 is, for example, a mixed gas of silane (SiH₄), hydrogen chloride (HCl), and hydrogen gas (H₂).

Hydrogen chloride (HCL) is an assist gas for suppressing the clustering of silicon. In addition, hydrogen chloride has a function of etching silicon-containing by-products deposited in the flow path for the first source gas SG1.

The hydrogen gas (He) is a carrier gas. As the carrier gas, for example, an argon gas (Ar) can also be used.

The second source gas SG2 is a carbon (C) source gas. The second source gas SG2 contains carbon (C). The second source gas SG2 contains, for example, hydrocarbon. The second source gas SG2 is, for example, a mixed gas of propane (C₃H₈) and hydrogen gas (H₂).

The second source gas SG2 contains, for example, a dopant gas of n-type impurities. The dopant gas of n-type impurities is, for example, a nitrogen gas.

The purge gas PG has a function of suppressing the first source gas SG1 supplied to the reactor 10 from entering the inside of the first purge gas conduit 73 from the reactor 10 side. In addition, the purge gas PG has a function of suppressing the second source gas SG2 supplied to the reactor 10 from entering the inside of the second purge gas conduit 74 from the reactor 10 side.

The purge gas PG contains chlorine (Cl) and hydrogen (H). The purge gas PG contains, for example, hydrogen chloride (HCl). The purge gas PG contains, for example, hydrogen gas (H₂). The purge gas PG is, for example, a mixed gas of hydrogen chloride (HCl) and hydrogen gas (H₂).

Instead of the hydrogen gas (H₂), for example, an argon gas (Ar) can be used.

The atomic concentration of chlorine in the purge gas PG is, for example, lower than the atomic concentration of chlorine in the first source gas SG1. The atomic concentration of chlorine in the purge gas PG is, for example, ⅕ or less of the atomic concentration of chlorine in the first source gas SG1. In addition, the purge gas PG introduced into the first purge gas supply pipe 83 and the purge gas PG introduced into the second purge gas supply pipe 84 may have different gas mixture ratios and different gas species.

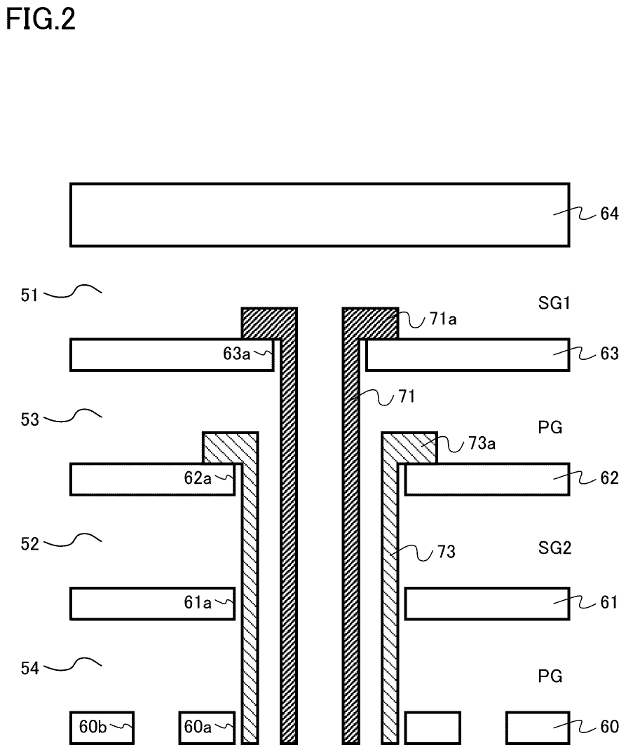

FIG. 2 is an enlarged schematic cross-sectional view of a part of a gas introduction unit in the vapor phase growth apparatus according to the first embodiment.

FIG. 2 is a cross-sectional view including the first source gas conduit 71 and the first purge gas conduit 73.

The first source gas conduit 71 supplies the first source gas SG1 to the reactor. The first source gas conduit 71 is inserted into the holes 60a, 61a, 62a, and 63a. The first source gas conduit 71 passes through the rectifying plate 60 and the partition plates 61, 62, and 63.

The first source gas conduit 71 has an annular flange 71a at its upper end. The first source gas conduit 71 is removable from the partition plate 63. The first source gas conduit 71 supports its own weight by placing the flange 71a on the partition plate 63.

The first purge gas conduit 73 supplies the purge gas PG to the reactor 10. The first purge gas conduit 73 is inserted into the holes 60a, 61a, and 62a. The first purge gas conduit 73 passes through the rectifying plate 60 and the partition plates 61 and 62.

The first purge gas conduit 73 has an annular flange 73a at its upper end. The first purge gas conduit 73 is removable from the partition plate 62. The first purge gas conduit 73 supports its own weight by placing the flange 73a on the partition plate 62.

The first source gas conduit 71 is inserted inside the first purge gas conduit 73. The first purge gas conduit 73 and the first source gas conduit 71 are spaced apart from each other. There is a gap between the first purge gas conduit 73 and the first source gas conduit 71. The gap between the first purge gas conduit 73 and the first source gas conduit 71 serves as a flow path for the purge gas PG.

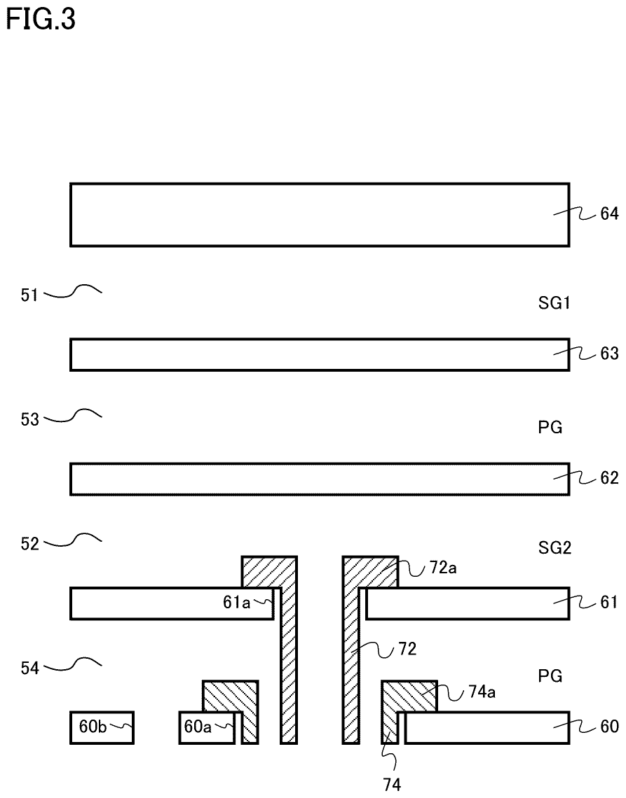

FIG. 3 is an enlarged schematic cross-sectional view of a part of a gas introduction unit in the vapor phase growth apparatus according to the first embodiment.

FIG. 3 is a cross-sectional view including the second source gas conduit 72 and the second purge gas conduit 74.

The second source gas conduit 72 supplies the second source gas SG2 to the reactor. The second source gas conduit 72 is inserted into the holes 60a and 61a. The second source gas conduit 72 passes through the rectifying plate 60 and the partition plate 61.

The second source gas conduit 72 has an annular flange 72a at its upper end. The second source gas conduit 72 is removable from the partition plate 61. The second source gas conduit 72 supports its own weight by placing the flange 72a on the partition plate 61.

The second purge gas conduit 74 supplies the purge gas PG to the reactor 10. The second purge gas conduit 74 is inserted into the hole 60a. The second purge gas conduit 74 passes through the rectifying plate 60.

The second purge gas conduit 74 has an annular flange 74a at its upper end. The second purge gas conduit 74 is removable from the rectifying plate 60. The second purge gas conduit 74 supports its own weight by placing the flange 74a on the rectifying plate 60.

The second source gas conduit 72 is inserted inside the second purge gas conduit 74. The second purge gas conduit 74 and the second source gas conduit 72 are spaced apart from each other. A flow path for the purge gas PG is provided between the second purge gas conduit 74 and the second source gas conduit 72. The hole 60b of the rectifying plate 60 also serves as a flow path for the purge gas PG.

The first source gas conduit 71, the second source gas conduit 72, the first purge gas conduit 73, and the second purge gas conduit 74 are formed of a highly heat-resistant material, for example, SiC-coated carbon. In addition, the rectifying plate 60 and the partition plates 61, 62, and 63 are formed of a highly heat-resistant material, such as SiC-coated carbon.

The control circuit 12 has a function of controlling the supply of the first source gas SG1, the second source gas SG2, and the purge gas PG into the reactor 10.

The control circuit 12 controls the first valve V1, the second valve V2, the third valve V3, the fourth valve V4, the first mass flow controller MFC1, the second mass flow controller MFC2, the third mass flow controller MFC3, and the fourth mass flow controller MFC4. The control circuit 12 is an example of a control unit.

The control circuit 12 controls, for example, the opening and closing of the first valve V1, the second valve V2, the third valve V3, and the fourth valve V4. For example, the control circuit 12 transmits command values for the gas flow rate to the first mass flow controller MFC1, the second mass flow controller MFC2, the third mass flow controller MFC3, and the fourth mass flow controller MFC4.

The control circuit 12 controls the flow rate of the first source gas SG1, for example, by transmitting a command value for the flow rate of the first source gas SG1 to the first mass flow controller MFC1. The control circuit 12 controls the flow rate of the second source gas SG2, for example, by transmitting a command value to the second mass flow controller MFC2. The control circuit 12 controls the flow rate of the purge gas PG, for example, by transmitting a command value to the third mass flow controller MFC3. The control circuit 12 controls the flow rate of the purge gas PG, for example, by transmitting a command value to the fourth mass flow controller MFC4.

The control circuit 12 is, for example, an electronic circuit. The control circuit 12 includes, for example, hardware and software.

The control circuit 12 includes, for example, a central processing unit (CPU). The control circuit 12 includes, for example, a storage device. The storage device included in the control circuit 12 is, for example, a semiconductor memory, a solid state device (SSD), or a hard disk.

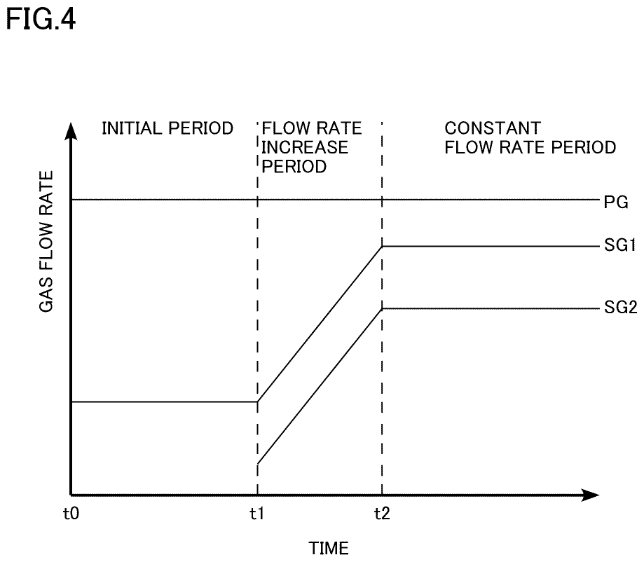

FIG. 4 is an explanatory diagram of control by the control circuit in the vapor phase growth apparatus according to the first embodiment. FIG. 4 is a diagram showing a change over time in the flow rate of the process gas supplied to the reactor 10 of the vapor phase growth apparatus 100. The flow rate of the process gas is controlled by the control circuit 12.

When forming an SiC film on the wafer W, the control circuit 12 performs control so that the supply of the first source gas SG1 and the purge gas PG to the reactor 10 starts at time to. Specifically, for example, at time to, the control circuit 12 transmits command signals to the first valve V1, the third valve V3, and the fourth valve V4 to open the first valve V1, the third valve V3, and the fourth valve V4, thereby starting supplying the first source gas SG1 and the purge gas PG to the reactor 10.

The control circuit 12 controls the flow rate of the first source gas SG1 and the flow rate of the purge gas to be desired flow rates. Specifically, for example, the control circuit 12 adjusts the opening degree of the first mass flow controller MFC1, the third mass flow controller MFC3, and the fourth mass flow controller MFC4 by transmitting command signals to the first mass flow controller MFC1, the third mass flow controller MFC3, and the fourth mass flow controller MFC4, thereby controlling the flow rate of the first source gas SG1 and the flow rate of the purge gas PG to be desired flow rates. In addition, in the following description, the flow rate of the purge gas PG is the sum of the flow rates of the purge gases PG supplied from the first purge gas supply pipe 83 and the second purge gas supply pipe 84.

The control circuit 12 controls the flow rate of the first source gas SG1 and the flow rate of the purge gas to be constant, for example, from time t0 to time t1. The period from time to and time t1 is referred to as an initial period. The initial period is an example of a first period.

The control circuit 12 performs control so that the supply of the second source gas SG2 to the reactor 10 starts at time t1. Specifically, for example, at time t1, the control circuit 12 transmits a command signal to the second valve V2 to open the second valve V2, thereby starting supplying the second source gas SG2 to the reactor 10.

The control circuit 12 controls the flow rate of the first source gas SG1 and the flow rate of the second source gas SG2 to increase, for example, from time t1 to time t2. In addition, the control circuit 12 controls the flow rate of the purge gas PG to be constant, for example, from time t1 to time t2. The period from time t1 to time t2 is referred to as a flow rate increase period. The flow rate increase period is an example of a second period.

The flow rate increase period is a period after the initial period. The flow rate increase period and the initial period are consecutive.

After time t2, the control circuit 12 controls the flow rate of the first source gas SG1, the flow rate of the second source gas SG2, and the flow rate of the purge gas to be constant. The period from time t2 is referred to as a constant flow rate period.

The constant flow rate period is a period after the flow rate increase period. The constant flow rate period and the flow rate increase period are consecutive.

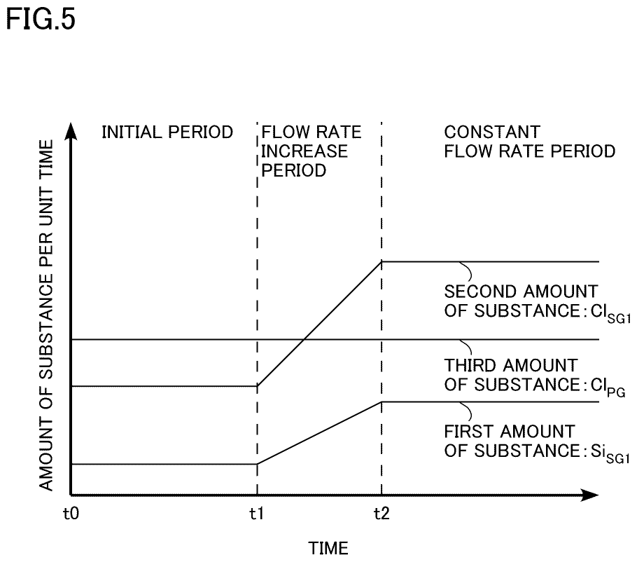

FIG. 5 is an explanatory diagram of control by the control circuit in the vapor phase growth apparatus according to the first embodiment. FIG. 5 is a diagram showing changes over time in the amount of substance of silicon (Si) per unit time and the amount of substance of chlorine (Cl) per unit time in the process gas supplied to the reactor 10 of the vapor phase growth apparatus 100. The amount of substance per unit time is controlled by the control circuit 12.

The control circuit 12 performs control so that, for example, a first amount of substance (Si_{SG1}) that is the amount of substance of silicon contained in the first source gas SG1 supplied to the reactor 10 per unit time, a second amount of substance (Cl_{SG1}) that is the amount of substance of chlorine contained in the first source gas SG1 supplied to the reactor 10 per unit time, and a third amount of substance (Cl_{PG}) that is the amount of substance of chlorine contained in the purge gas PG supplied to the reactor 10 per unit time are constant in the initial period.

The first amount of substance (Si_{SG1}) can be calculated from the flow rate of the first source gas SG1 and the atomic concentration of silicon contained in the first source gas SG1. In addition, the second amount of substance (Cl_{SG1}) can be calculated from the flow rate of the first source gas SG1 and the atomic concentration of chlorine contained in the first source gas SG1. In addition, the third amount of substance (Cl_{PG}) can be calculated from the flow rate of the purge gas PG and the atomic concentration of chlorine contained in the purge gas PG.

If the atomic concentration of silicon contained in the first source gas SG1 and the atomic concentration of chlorine contained in the first source gas SG1 are constant, in the initial period, the first amount of substance (Si_{SG1}) and the second amount of substance (Cl_{SG1}) are constant as shown in FIG. 5 if the flow rate of the first source gas SG1 is kept constant as shown in FIG. 4. In this case, the ratio of the second amount of substance (Cl_{SG1}) to the first amount of substance (Si_{SG1}) (second amount of substance/first amount of substance) is constant.

For example, if the atomic concentration of chlorine contained in the purge gas PG is constant, the third amount of substance (Cl_{PG}) is constant in the initial period as shown in FIG. 5 if the flow rate of the purge gas PG is kept constant as shown in FIG. 4.

The control circuit 12 performs control so that, for example, the first amount of substance (Si_{SG1}) and the second amount of substance (Cl_{SG1}) increase in the flow rate increase period. In addition, for example, the control circuit 12 performs control so that the third amount of substance (Cl_{PG}) is constant in the flow rate increase period.

If the atomic concentration of silicon contained in the first source gas SG1 and the atomic concentration of chlorine contained in the first source gas SG1 are constant, in the flow rate increase period, the first amount of substance (Si_{SG1}) and the second amount of substance (Cl_{SG1}) increase as shown in FIG. 5 as the flow rate of the first source gas SG1 increases as shown in FIG. 4. In this case, the ratio of the second amount of substance (Cl_{SG1}) to the first amount of substance (Si_{SG1}) (second amount of substance/first amount of substance) is kept constant.

For example, if the atomic concentration of chlorine contained in the purge gas PG is constant, in the flow rate increase period, the third amount of substance (Cl_{PG}) is constant as shown in FIG. 5 if the flow rate of the purge gas PG is kept constant as shown in FIG. 4. The control circuit 12 performs control so that,

for example, the first amount of substance (Si_{SG1}), the second amount of substance (Cl_{SG1}), and the third amount of substance (Cl_{PG}) are constant in the constant flow rate period.

If the atomic concentration of silicon contained in the first source gas SG1 and the atomic concentration of chlorine contained in the first source gas SG1 are constant, in the constant flow rate period, the first amount of substance (Si_{SG1}) and the second amount of substance (Cl_{SG1}) are constant as shown in FIG. 5 if the flow rate of the first source gas SG1 is kept constant as shown in FIG. 4. In this case, the ratio of the second amount of substance (Cl_{SG1}) to the first amount of substance (Si_{SG1}) (second amount of substance/first amount of substance) is kept constant.

For example, if the atomic concentration of chlorine contained in the purge gas PG is constant, in the constant flow rate period, the third amount of substance (Cl_{PG}) is constant as shown in FIG. 5 if the flow rate of the purge gas PG is kept constant as shown in FIG. 4.

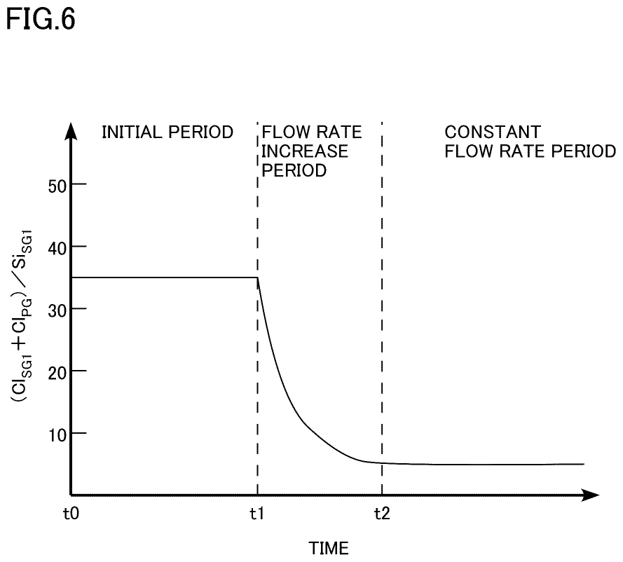

FIG. 6 is an explanatory diagram of control by the control circuit in the vapor phase growth apparatus according to the first embodiment. FIG. 6 is a diagram showing a change over time in the ratio ((second amount of substance+third amount of substance)/first amount of substance) of the sum of the second amount of substance (Cl_{SG1}) and the third amount of substance (Cl_{PG}) to the first amount of substance (Si_{SG1}). (Second amount of substance+third amount of substance)/first amount of substance is controlled by the control circuit 12.

The control circuit 12 controls the ratio ((second amount of substance+third amount of substance)/first amount of substance) of the sum of the second amount of substance (Cl_{SG1}) and the third amount of substance (Cl_{PG}) to the first amount of substance (Si_{SG1}) to be 30 or more in the initial period. (Second amount of substance+third amount of substance)/first amount of substance can be expressed as (Cl_{SG1}+Cl_{PG})/Si_{SG1}.

The control circuit 12 can set (second amount of substance+third amount of substance)/first amount of substance to 30 or more by controlling the flow rate of the first source gas SG1 and the flow rate of the purge gas PG in consideration of the atomic concentration of silicon and the atomic concentration of chlorine contained in the first source gas SG1 and the atomic concentration of chlorine contained in the purge gas PG. (Second amount of substance+third amount of substance)/first amount of substance is, for example, 30 or more and 200 or less.

The control circuit 12 controls the flow rates of the first source gas SG1 and the purge gas PG as shown in FIG. 4, so that (second amount of substance+third amount of substance)/first amount of substance is kept constant in the initial period as shown in FIG. 6. In addition, by controlling the flow rates of the first source gas SG1 and the purge gas PG as shown in FIG. 4, (second amount of substance+third amount of substance)/first amount of substance decreases in the flow rate increase period as shown in FIG. 6. In addition, by controlling the flow rates of the first source gas SG1 and the purge gas PG as shown in FIG. 4, (second amount of substance+third amount of substance)/first amount of substance is kept constant in the constant flow rate period as shown in FIG. 6. For example, the control circuit 12 controls the flow rate of the first source gas SG1 and the flow rate of the second source gas SG2 so that the ratio (fourth amount of substance/first amount of substance) of a fourth amount of substance (C_{SG2}), which is the amount of substance of carbon contained in the second source gas SG2 supplied to the reactor 10 per unit time, to the first amount of substance (Si_{SG1}) is 1.2 or less.

The fourth amount of substance (C_{SG2}) can be calculated from the flow rate of the second source gas SG2 and the atomic concentration of carbon contained in the second source gas SG2.

Next, a vapor phase growth method according to the first embodiment will be described. The vapor phase growth method according to the first embodiment is a vapor phase growth method for forming a silicon carbide film on a substrate placed on a holder provided in a reactor, and includes: supplying a first source gas containing silicon and chlorine and a purge gas containing chlorine and hydrogen into the reactor so that a ratio ((second amount of substance+third amount of substance)/first amount of substance) of a sum of a second amount of substance as an amount of substance of chlorine contained in the first source gas supplied to the reactor per unit time and a third amount of substance as an amount of substance of chlorine contained in the purge gas supplied to the reactor per unit time to a first amount of substance as an amount of substance of silicon contained in the first source gas supplied to the reactor per unit time is 30 or more in a first period; and increasing a flow rate of the first source gas supplied into the reactor in a second period after the first period.

In the vapor phase growth method according to the first embodiment, the vapor phase growth apparatus 100 shown in FIG. 1 is used. Hereinafter, a case of forming a single crystal SiC film 13 (silicon carbide film) on the surface of the wafer W of single crystal SiC will be described as an example.

The first source gas SG1 contains silicon and chlorine. The second source gas SG2 contains carbon. The purge gas PG contains chlorine and hydrogen.

Hereinafter, a case where the first source gas SG1 is a mixed gas of silane (SiH₄), hydrogen chloride (HCl), and hydrogen gas (H₂), the second source gas SG2 is a mixed gas of propane (C₃H₈) and hydrogen gas (H₂), and the purge gas PG is a mixed gas of hydrogen chloride (HCl) and hydrogen gas (H₂) will be described as an example.

The atomic concentration of silicon in the first source gas SG1, the atomic concentration of chlorine in the first source gas SG1, the atomic concentration of carbon in the second source gas SG2, and the atomic concentration of chlorine in the purge gas PG are each kept constant.

First, the susceptor 14 on which the wafer W is placed is loaded into the reactor 10. The wafer W is formed of single crystal SiC.

Then, the wafer W is rotated at a rotation speed of 300 rpm or more by the rotation driving mechanism 20. Then, the wafer W is heated by the first heater 22 and the second heater 42.

Then, as shown in FIG. 4, at time to, the supply of the first source gas SG1 into the reactor 10 is started. The first source gas SG1 is introduced from the first source gas supply pipe 81 into the first source gas region 51 and is supplied to the reactor 10 through the first source gas conduit 71. The flow rate of the first source gas SG1 is controlled by the control circuit 12.

In addition, as shown in FIG. 4, at time to, the supply of the purge gas PG to the reactor 10 is started. The purge gas PG is introduced from the first purge gas supply pipe 83 into the first purge gas region 53, and is supplied to the reactor 10 through the first purge gas conduit 73. In addition, the purge gas PG is introduced from the second purge gas supply pipe 84 into the second purge gas region 54, and is supplied to the reactor 10 through the second purge gas conduit 74 and the hole 60b of the rectifying plate 60. The flow rate of the purge gas PG is controlled by the control circuit 12.

As shown in FIG. 4, from time t0 to time t1, that is, during the initial period, for example, the flow rate of the first source gas SG1 is kept constant. In addition, during the initial period, for example, the flow rate of the purge gas PG is kept constant.

As shown in FIG. 5, during the initial period, for example, the first amount of substance (Si_{SG1}) and the second amount of substance (Cl_{SG1}) are kept constant. In addition, as shown in FIG. 5, during the initial period, for example, the third amount of substance (Cl_{PG}) is kept constant.

In addition, as shown in FIG. 6, the first source gas SG1 and the purge gas PG are supplied to the reactor 10 so that the ratio ((second amount of substance+third amount of substance)/first amount of substance) of the sum of the second amount of substance (Cl_{SG1}) and the third amount of substance (Cl_{PG}) to the first amount of substance (Si_{SG1}) is 30 or more in the initial period. In the initial period, (second amount of substance+third amount of substance)/first amount of substance is, for example, constant.

In addition, during the initial period, the second source gas SG2, which is a source gas of carbon (C), is not supplied into the reactor 10, so that the SiC film 13 is not formed on the surface of the wafer W.

Then, as shown in FIG. 4, at time t1, the supply of the second source gas SG2 into the reactor 10 is started. The second source gas SG2 is introduced from the second source gas supply pipe 82 into the second source gas region 52, and is supplied to the reactor 10 through the second source gas conduit 72. The flow rate of the second source gas SG2 is controlled by the control circuit 12.

The first source gas SG1, the second source gas SG2, and the purge gas PG supplied from the gas introduction unit 11 into the reactor 10 form a gas flow toward the surface of the wafer W. Silicon atoms contained in the first source gas SG1 and carbon atoms contained in the second source gas SG2 react with each other on the surface of the wafer W, forming the single crystal SiC film 13 on the surface of the wafer W.

As shown in FIG. 4, in the flow rate increase period after the initial period, the flow rate of the first source gas SG1 and the flow rate of the second source gas SG2 are increased. In addition, as shown in FIG. 4, in the initial period and the flow rate increase period, the flow rate of the purge gas PG is kept constant.

As shown in FIG. 5, in the flow rate increase period, the first amount of substance (Si_{SG1}) and the second amount of substance (Cl_{SG1}) increase. In addition, as shown in FIG. 5, for example, in the initial period and the flow rate increase period, the third amount of substance (Cl_{PG}) is kept constant.

In the initial period and the flow rate increase period, for example, the ratio (second amount of substance/first amount of substance) of the second amount of substance (Cl_{SG1}) to the first amount of substance (Si_{SG1}) is kept constant.

As shown in FIG. 4, in the constant flow rate period after the flow rate increase period, the flow rate of the first source gas SG1, the flow rate of the second source gas SG2, and the flow rate of the purge gas PG are kept constant.

In the flow rate increase period and the constant flow rate period, for example, the ratio (fourth amount of substance/first amount of substance) of the fourth amount of substance (C_{SG2}) to the first amount of substance (Si_{SG1}) is 0.1 or more and 1.2 or less.

After the SiC film 13 is formed, the heating by the first heater 22 and the second heater 42 is stopped to lower the temperature of the wafer W. Thereafter, the wafer W is unloaded from the reactor 10 together with the susceptor 14.

Next, the function and effect of the vapor phase growth apparatus and the vapor phase growth method according to the first embodiment will be described.

When forming an SiC film on the surface of a wafer using a vapor phase growth apparatus, defects such as pits and bumps may occur on the surface of the SiC film. If there are defects on the surface of the SiC film, for example, the characteristics of a semiconductor device formed on the SiC film deteriorate, which causes a problem.

In the vapor phase growth apparatus 100 according to the first embodiment, when forming an SiC film on the surface of a wafer, the control circuit 12 controls the supply of a first source gas containing silicon and chlorine and a purge gas containing chlorine and hydrogen to the reactor 10. The control circuit 12 controls, for example, the flow rate of the first source gas and the flow rate of the purge gas.

The control circuit 12 controls the ratio ((second amount of substance+third amount of substance)/first amount of substance) of the sum of the second amount of substance, which is the amount of substance of chlorine contained in the first source gas SG1 supplied to the reactor 10 per unit time, and the third amount of substance, which is the amount of substance of chlorine contained in the purge gas PG supplied to the reactor 10 per unit time, to the first amount of substance, which is the amount of substance of silicon contained in the first source gas SG1 supplied to the reactor 10 per unit time, to be 30 or more in the initial period when forming the SiC film on the surface of the wafer.

In addition, the control circuit 12 controls the flow rate of the first source gas SG1 so that the flow rate of the first source gas SG1 increases in the flow rate increase period after the initial period.

According to the vapor phase growth apparatus 100 according to the first embodiment, the above-described configuration makes it possible to suppress the occurrence of defects, such as pits and bumps, on the surface of the SiC film when the SiC film is formed on the surface of the wafer.

In addition, in the vapor phase growth method according to the first embodiment, in the initial period when forming the SiC film on the surface of the wafer, the first source gas SG1 containing silicon and chlorine and the purge gas PG containing chlorine and hydrogen are supplied into the reactor 10 so that the ratio ((second amount of substance+third amount of substance)/first amount of substance) of the sum of the second amount of substance, which is the amount of substance of chlorine contained in the first source gas SG1 supplied to the reactor 10 per unit time, and the third amount of substance, which is the amount of substance of chlorine contained in the purge gas PG supplied to the reactor 10 per unit time, to the first amount of substance, which is the amount of substance of silicon contained in the first source gas SG1 supplied to the reactor 10 per unit time, is 30 or more. In addition, in the flow rate increase period after the initial period, the flow rate of the first source gas SG1 supplied into the reactor 10 is increased.

According to the vapor phase growth method according to the first embodiment, the above-described configuration makes it possible to suppress the occurrence of defects, such as pits and bumps, on the surface of the SiC film when the SiC film is formed on the surface of the wafer.

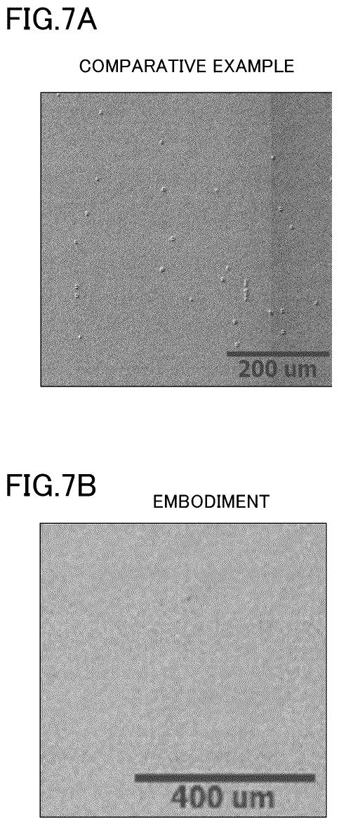

FIGS. 7A and 7B are explanatory diagrams of the function and effect of the first embodiment. FIGS. 7A and 7B are photographs of the surface of the SiC film using a confocal differential interference contrast microscope. FIG. 7A shows an SiC film manufactured using a vapor phase growth method according to a comparative example, and FIG. 7B shows an SiC film manufactured using the vapor phase growth method according to embodiments.

In the vapor phase growth method according to the comparative example, in the initial period, (second amount of substance+third amount of substance)/first amount of substance, that is, (Cl_{SG1}+Cl_{PG})/Si_{SG1} is 24.5. In addition, in the comparative example, in the flow rate increase period and the constant flow rate period, the ratio (fourth amount of substance/first amount of substance) of the fourth amount of substance to the first amount of substance, that is, C_{SG2}/Si_{SG1}, is 0.95.

On the other hand, in the vapor phase growth method according to embodiments, (second amount of substance+third amount of substance)/first amount of substance, that is, (Cl_{SG1}+Cl_{PG})/Si_{SG1} is 32.75. In addition, in the vapor phase growth method according to embodiments, in the flow rate increase period and the constant flow rate period, the ratio (fourth amount of substance/first amount of substance) of the fourth amount of substance to the first amount of substance, that is, C_{SG2}/Si_{SG1}, is 0.95. In the vapor phase growth method according to embodiments, the second amount of substance, which is the amount of substance of chlorine contained in the first source gas SG1, is increased to about 1.8 times that in the comparative example, thereby increasing (second amount of substance+third amount of substance)/first amount of substance in the initial period.

As shown in FIG. 7A, in the comparative example, the occurrence of defects such as pits or bumps are observed on the surface of the SiC film. On the other hand, as shown in FIG. 7B, in embodiments, the occurrence of defects such as pits or bumps on the surface of the SiC film is suppressed.

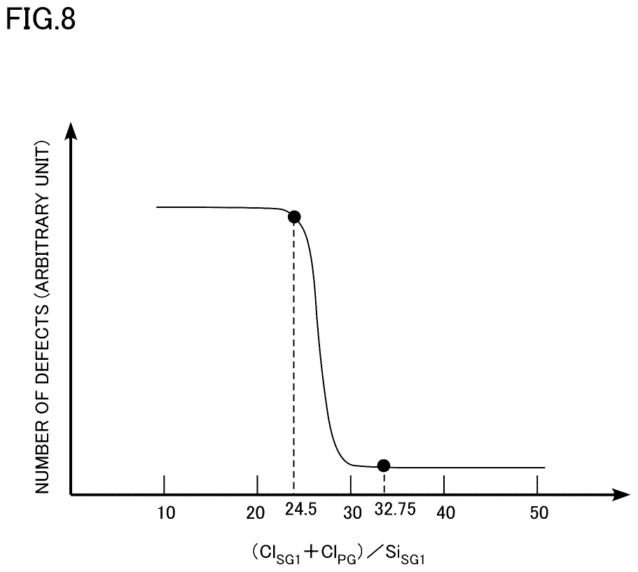

FIG. 8 is an explanatory diagram of the function and effect of the vapor phase growth apparatus and the vapor phase growth method according to the first embodiment. FIG. 8 is a diagram showing a relationship between the number of defects on the surface of an SiC film and the ratio ((second amount of substance+third amount of substance)/first amount of substance) of the sum of the second amount of substance and the third amount of substance to the first amount of substance in the initial period. FIG. 8 shows the number of defects on the surface of the SiC film when only the ratio ((second amount of substance+third amount of substance)/first amount of substance) of the sum of the second amount of substance and the third amount of substance to the first amount of substance is changed in a vapor phase growth method similar to the vapor phase growth method according to the first embodiment.

As shown in FIG. 8, when (second amount of substance+third amount of substance)/first amount of substance, that is, (Cl_{SG1}+Cl_{PG})/Si_{SG1} is 30 or more, the number of defects on the surface of the SiC film is reduced. (second amount of substance+third amount of substance)/first amount of substance is, for example, 200 or less.

It is believed that the generation of particles containing silicon in the reactor 10 is suppressed by increasing the ratio of chlorine to silicon supplied to the reactor 10 in the initial stage of formation of the SiC film.

From the viewpoint of reducing the number of defects on the surface of the SiC film, (second amount of substance+third amount of substance)/first amount of substance is preferably 35 or more, and more preferably 40 or more.

From the viewpoint of stably forming the SiC film, it is preferable that the supply of the second source gas SG2 containing carbon into the reactor 10 is started after the initial period.

From the viewpoint of stably forming the SiC film, it is preferable that the ratio (second amount of substance/first amount of substance) of the second amount of substance (Cl_{SG1}) to the first amount of substance (Si_{SG1}) is constant in the initial period, the flow rate increase period, and the constant flow rate period.

From the viewpoint of stably forming the SiC film, it is preferable that the third amount of substance (Cl_{PG}) is constant in the initial period, the flow rate increase period, and the constant flow rate period.

The ratio (fourth amount of substance/first amount of substance) of the fourth amount of substance (C_{SG2}) to the first amount of substance (Si_{SG1}), that is, C_{SG2}/Si_{SG1}, is adjusted to obtain desired characteristics of the SiC film to be formed. For example, by adjusting the C_{SG2}/Si_{SG1} ratio, it is possible to adjust the uniformity of the carrier concentration in the SiC film or the film formation rate.

From the viewpoint of stably forming the SiC film, it is preferable that, at the time when the supply of the second source gas SG2 to the reactor 10 is started, the fourth amount of substance (C_{SG2}) of carbon contained in the second source gas SG2 supplied to the reactor 10 per unit time is fixed to a predetermined amount of substance independent of C_{SG2}/Si_{SG1} during film formation.

When the fourth amount of substance (C_{SG2}) of carbon contained in the second source gas SG2 is fixed to a predetermined amount of substance independent of C_{SG2}/Si_{SG1}, the first amount of substance (Si_{SG1}) inevitably increases if the film formation conditions under which C_{SG2}/Si_{SG1} is small are selected. As the first amount of substance (Si_{SG1}) increases, (second amount of substance+third amount of substance)/first amount of substance decreases. For this reason, it is desirable to adjust (second amount of substance+third amount of substance)/first amount of substance to 30 or more by increasing at least one of the second amount of substance and the third amount of substance.

For example, when fourth amount of substance/first amount of substance, that is, C_{SG2}/Si_{SG1}, is 1.2 or less, it is preferable to increase at least one of the second amount of substance (Cl_{SG1}) and the third amount of substance (Cl_{PG}) so that (second amount of substance+third amount of substance)/first amount of substance is 30 or more.

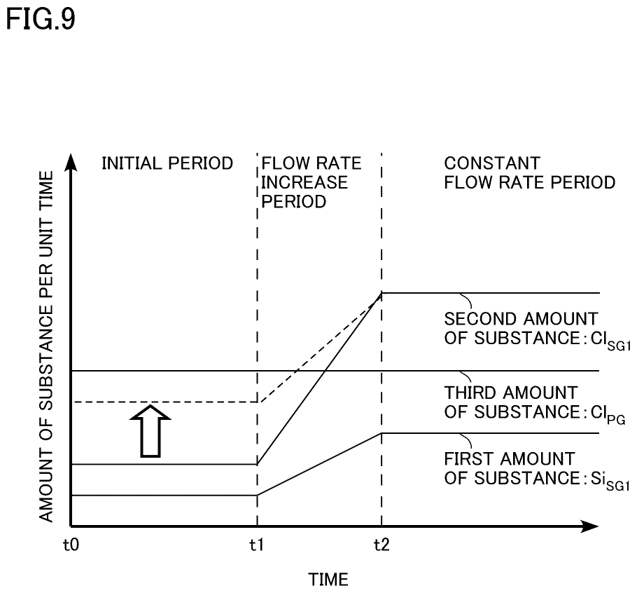

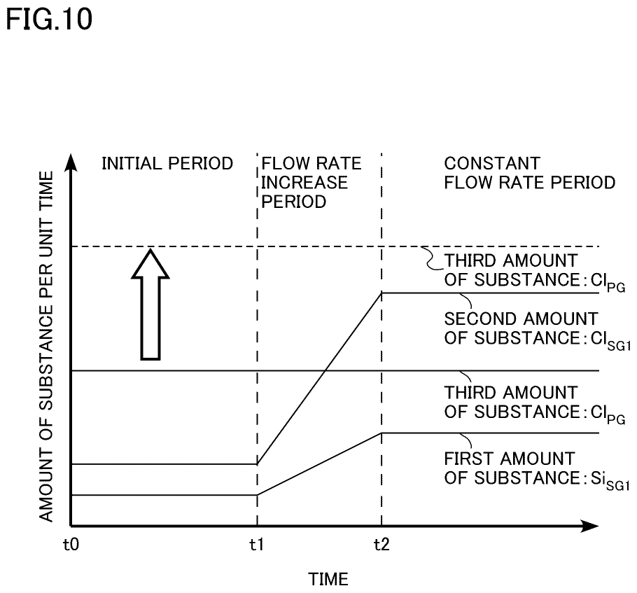

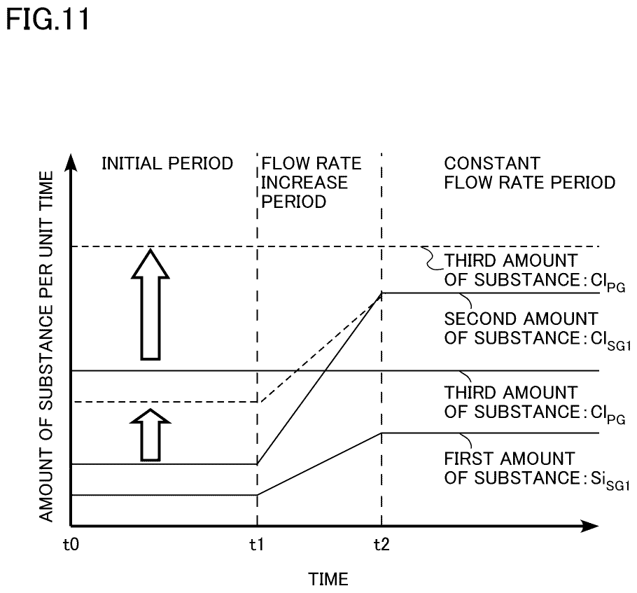

FIGS. 9, 10, and 11 are explanatory diagrams of the vapor phase growth apparatus and the vapor phase growth method according to the first embodiment. For example, in order to set (second amount of substance+third amount of substance)/first amount of substance to 30 or more in the initial state, only the second amount of substance (Cl_{SG1}) may be increased as shown in FIG. 9. In addition, for example, in order to set (second amount of substance+third amount of substance)/first amount of substance to 30 or more in the initial state, only the third amount of substance (Cl_{PG}) may be increased as shown in FIG. 10. In addition, for example, in order to set (second amount of substance+third amount of substance)/first amount of substance to 30 or more in the initial state, both the second amount of substance (Cl_{SG1}) and the third amount of substance (Cl_{PG}) may be increased as shown in FIG. 11.

As described above, according to the first embodiment, it is possible to realize a vapor phase growth apparatus and a vapor phase growth method capable of reducing defects in a film.

### Second Embodiment

A vapor phase growth apparatus according to a second embodiment is different from the vapor phase growth apparatus according to the first embodiment in that a mixed source gas flow path for supplying a mixed source gas containing silicon, carbon, and chlorine into the reactor is provided. In addition, a vapor phase growth method according to a second embodiment is different from the vapor phase growth method according to the first embodiment in that a mixed source gas containing silicon, carbon, and chlorine is supplied into the reactor. Hereinafter, the description of a part of the content overlapping the first embodiment may be omitted.

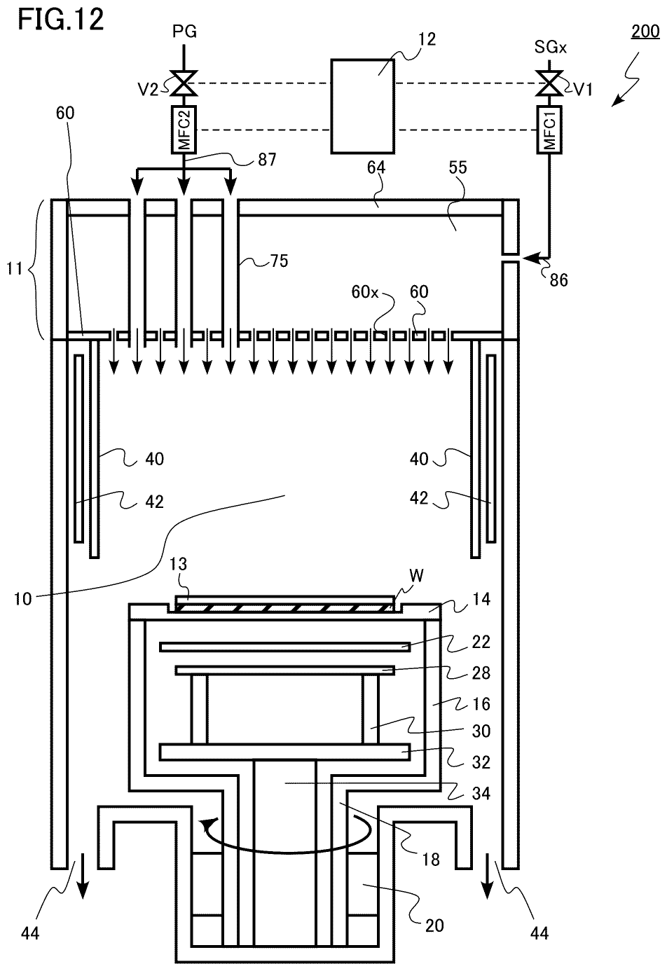

FIG. 12 is a schematic cross-sectional view of the vapor phase growth apparatus according to the second embodiment. A vapor phase growth apparatus 200 according to the second embodiment is, for example, a single wafer type epitaxial growth apparatus that epitaxially grows a single crystal SiC film on a single crystal SiC substrate. The vapor phase growth apparatus 200 according to the second embodiment is a vertical vapor phase growth apparatus in which a process gas is supplied in a vertical direction to the surface of the SiC substrate.

The vapor phase growth apparatus 200 according to the second embodiment includes a reactor 10, a gas introduction unit 11, and a control circuit 12 (control unit). The reactor 10 includes a susceptor 14 (holder), a rotating body 16, a rotating shaft 18, a rotation driving mechanism 20, a first heater 22, a reflector 28, a support column 30, a fixing table 32, a fixing shaft 34, a hood 40, a second heater 42, and a gas exhaust port 44. The gas introduction unit 11 includes a mixed source gas region 55, a rectifying plate 60, a top plate 64, and a purge gas conduit 75. The rectifying plate 60 includes a gas hole 60x.

The vapor phase growth apparatus 200 according to the second embodiment includes a mixed source gas supply pipe 86, a purge gas supply pipe 87, a first mass flow controller MFC1, a second mass flow controller MFC2, a first valve V1, and a second valve V2.

The mixed source gas supply pipe 86, the mixed source gas region 55, and the gas hole 60x form a source gas flow path. The source gas flow path supplies a mixed source gas SGx to the reactor 10.

The purge gas supply pipe 87 and the purge gas conduit 75 form a purge gas flow path. The purge gas flow path supplies a purge gas PG to the reactor 10.

The first valve V1 and the first mass flow controller MFC1 are provided in the mixed source gas supply pipe 86. The first valve V1 has a function of switching between starting and stopping the introduction of the mixed source gas SGx introduced into the mixed source gas supply pipe 86. The first mass flow controller MFC1 has a function of adjusting the flow rate of the mixed source gas SGx introduced into the mixed source gas supply pipe 86 to a predetermined amount.

The second valve V2 and the second mass flow controller MFC2 are provided in the purge gas supply pipe 87. The second valve V2 has a function of switching between starting and stopping the introduction of the purge gas PG introduced into the purge gas supply pipe 87. The second mass flow controller MFC2 has a function of adjusting the flow rate of the purge gas PG introduced into the purge gas supply pipe 87 to a predetermined amount.

The first valve V1, the second valve V2, the first mass flow controller MFC1, and the second mass flow controller MFC2 are controlled by the control circuit 12.

The gas introduction unit 11 is provided above the reactor 10.

The mixed source gas SGx is introduced into the mixed source gas region 55 from the mixed source gas supply pipe 86. The mixed source gas region 55 is provided between the rectifying plate 60 and the top plate 64.

The rectifying plate 60 is provided between the reactor 10 and the mixed source gas region 55. The rectifying plate 60 has a plurality of gas holes 60x.

The top plate 64 is provided above the mixed source gas region 55.

The mixed source gas SGx is a source gas of silicon (Si) and carbon (C). The mixed source gas SGx contains silicon (Si), carbon (C), and chlorine (Cl). The mixed source gas SGx contains, for example, silane (SiH₄) or silane chloride (SiH₄₋ₙClₙ:n=1 to 4). The mixed source gas SGx contains, for example, hydrocarbon. The mixed source gas SGx contains, for example, hydrogen chloride (HCl). The mixed source gas SGx contains, for example, hydrogen gas (H₂). The mixed source gas SGx is, for example, a mixed gas of silane (SiH₄), propane (C₃H₈), hydrogen chloride (HCl), and hydrogen gas (H₂).

The mixed source gas SGx contains, for example, a dopant gas of n-type impurities. The dopant gas of n-type impurities is, for example, a nitrogen gas.

The purge gas PG has a function of adjusting the distribution of the mixed source gas SGx supplied to the reactor 10 on the wafer W, for example.

The purge gas PG contains chlorine (Cl) and hydrogen (H). The purge gas PG contains, for example, hydrogen chloride (HCl). The purge gas PG contains, for example, hydrogen gas (H₂). The purge gas PG is, for example, a mixed gas of hydrogen chloride (HCl) and hydrogen gas (H₂). Instead of hydrogen gas (H₂), for example, an argon gas (Ar) can be used.

The atomic concentration of chlorine in the purge gas PG is, for example, lower than the atomic concentration of chlorine in the mixed source gas SGx. The atomic concentration of chlorine in the purge gas PG is, for example, ⅕ or less of the atomic concentration of chlorine in the mixed source gas SGx.

The control circuit 12 controls the first valve V1, the second valve V2, the first mass flow controller MFC1, and the second mass flow controller MFC2. The control circuit 12 is an example of a control unit.

The control circuit 12 controls, for example, the opening and closing of the first valve V1 and the opening and closing of the second valve V2. The control circuit 12 transmits, for example, command values for gas flow rates to the first mass flow controller MFC1 and the second mass flow controller MFC2.

The control circuit 12 controls the flow rate of the mixed source gas SGx, for example, by transmitting a command value for the flow rate of the mixed source gas SGx to the first mass flow controller MFC1. The control circuit 12 controls the flow rate of the purge gas PG, for example, by transmitting a command value to the second mass flow controller MFC2.

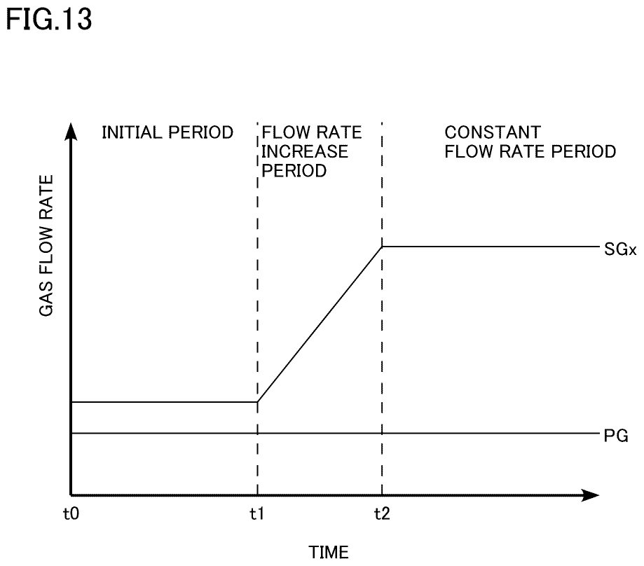

FIG. 13 is an explanatory diagram of control by a control circuit in the vapor phase growth apparatus according to the second embodiment. FIG. 13 is a diagram showing a change over time in the flow rate of the process gas supplied to the reactor 10 of the vapor phase growth apparatus 200. The flow rate of the process gas is controlled by the control circuit 12.

When forming an SiC film on the wafer W, the control circuit 12 performs control so that the supply of the mixed source gas SGx and the purge gas PG to the reactor 10 is started at time to. Specifically, for example, at time to, the control circuit 12 transmits command signals to the first valve V1 and the second valve V2 to open the first valve V1 and the second valve V2, thereby starting supplying the mixed source gas SGx and the purge gas PG to the reactor 10.

The control circuit 12 controls the flow rates of the mixed source gas SGx and the purge gas PG to be desired flow rates. Specifically, for example, the control circuit 12 adjusts the opening degree of the first mass flow controller MFC1 and the second mass flow controller MFC2 by transmitting command signals to the first mass flow controller MFC1 and the second mass flow controller MFC2, thereby controlling the flow rate of the mixed source gas SGx and the flow rate of the purge gas PG to be desired flow rates.

The control circuit 12 controls the flow rate of the mixed source gas SGx and the flow rate of the purge gas to be constant, for example, from time t0 to time t1. The period from time to and time t1 is referred to as an initial period. The initial period is an example of a first period.

The control circuit 12 controls the flow rate of the mixed source gas SGx to increase, for example, from time t1 to time t2. In addition, the control circuit 12 controls the flow rate of the purge gas PG to be constant, for example, from time t1 to time t2. The period from time t1 to time t2 is referred to as a flow increase period. The flow rate increase period is an example of a second period.

The flow rate increase period is a period after the initial period. The flow rate increase period and the initial period are consecutive.

After time t2, the control circuit 12 controls the flow rate of the mixed source gas SGx and the flow rate of the purge gas to be constant. The period from time t2 is referred to as a constant flow rate period.

The constant flow rate period is a period after the flow rate increase period. The constant flow rate period and the flow rate increase period are consecutive.

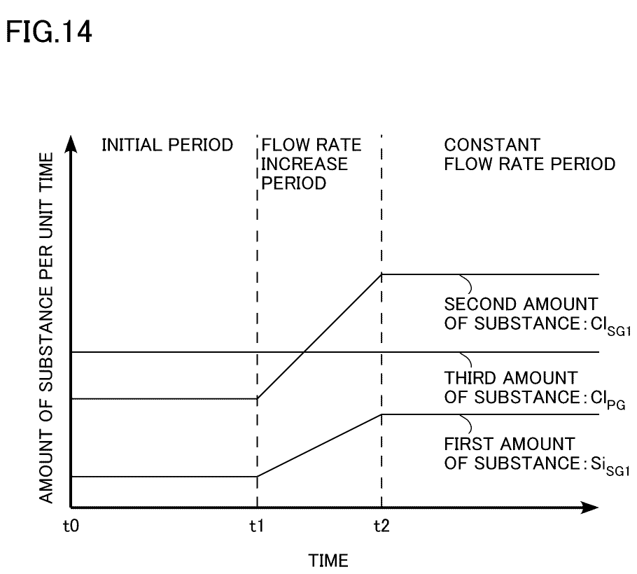

FIG. 14 is an explanatory diagram of control by a control circuit in the vapor phase growth apparatus according to the second embodiment. FIG. 14 is a diagram showing changes over time in the amount of substance of silicon (Si) per unit time and the amount of substance of chlorine (Cl) per unit time in the process gas supplied to the reactor 10 of the vapor phase growth apparatus 200. The amount of substance per unit time is controlled by the control circuit 12.

The control circuit 12 performs control so that, for example, a first amount of substance (Si_{SGx}), which is the amount of substance of silicon contained in the mixed source gas SGx supplied to the reactor 10 per unit time, a second amount of substance (Cl_{SGx}), which is the amount of substance of chlorine contained in the mixed source gas SGx supplied to the reactor 10 per unit time, and a third amount of substance (Cl_{PG}), which is the amount of substance of chlorine contained in the purge gas PG supplied to the reactor 10 per unit time, are constant in the initial period.

If the atomic concentration of silicon contained in the mixed source gas SGx and the atomic concentration of chlorine contained in the mixed source gas SGx are constant, in the initial period, the first amount of substance (Si_{SGx}) and the second amount of substance (Cl_{SGx}) are constant as shown in FIG. 14 if the flow rate of the mixed source gas SGx is kept constant as shown in FIG. 13. In this case, the ratio (second amount of substance/first amount of substance) of the second amount of substance (Cl_{SGx}) to the first amount of substance (Si_{SGx}) is constant.

For example, if the atomic concentration of chlorine contained in the purge gas PG is constant, in the initial period, the third amount of substance (Cl_{PG}) is constant as shown in FIG. 14 if the flow rate of the purge gas PG is kept constant as shown in FIG. 13.

The control circuit 12 performs control so that, for example, the first amount of substance (Si_{SGx}) and the second amount of substance (Cl_{SGx}) increase in the flow rate increase period. In addition, the control circuit 12 performs control so that, for example, the third amount of substance (Cl_{PG}) is constant in the flow rate increase period.

If the atomic concentration of silicon contained in the mixed source gas SGx and the atomic concentration of chlorine contained in the mixed source gas SGx are constant, in the flow rate increase period, the first amount of substance (Si_{SGx}) and the second amount of substance (Cl_{SGx}) increase as shown in FIG. 14 if the flow rate of the mixed source gas SGx is increased as shown in FIG. 13. In this case, the ratio (second amount of substance/first amount of substance) of the second amount of substance (Cl_{SGx}) to the first amount of substance (Si_{SGx}) is kept constant.

For example, if the atomic concentration of chlorine contained in the purge gas PG is constant, in the flow rate increase period, the third amount of substance (Cl_{PG}) is constant as shown in FIG. 14 if the flow rate of the purge gas PG is kept constant as shown in FIG. 13. The control circuit 12 performs control so that,

for example, the first amount of substance (Si_{SGx}), the second amount of substance (Cl_{SGx}), and the third amount of substance (Cl_{PG}) are constant in the constant flow rate period.

If the atomic concentration of silicon contained in the mixed source gas SGx and the atomic concentration of chlorine contained in the mixed source gas SGx are constant, in the constant flow rate period, the first amount of substance (Si_{SGx}) and the second amount of substance (Cl_{SGx}) are constant as shown in FIG. 14 if the flow rate of the mixed source gas SGx is kept constant as shown in FIG. 13. In this case, the ratio (second amount of substance/first amount of substance) of the second amount of substance (Cl_{SGx}) to the first amount of substance (Si_{SGx}) is kept constant.

For example, if the atomic concentration of chlorine contained in the purge gas PG is constant, in the constant flow rate period, the third amount of substance (Cl_{PG}) is constant as shown in FIG. 14 if the flow rate of the purge gas PG is kept constant as shown in FIG. 13.

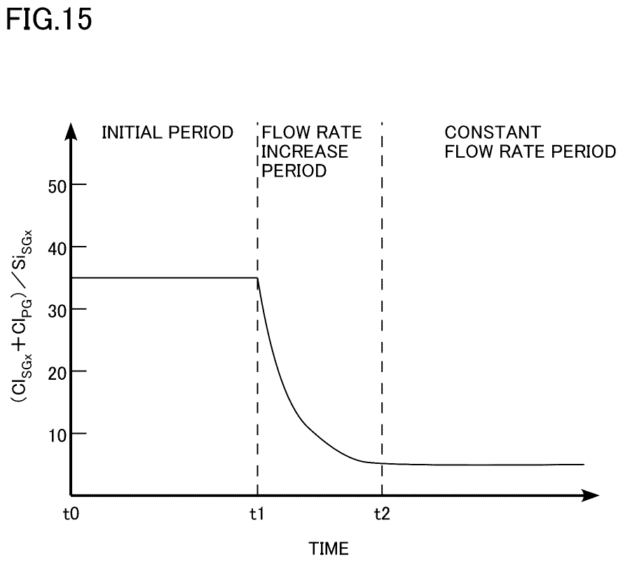

FIG. 15 is an explanatory diagram of control by a control circuit in the vapor phase growth apparatus according to the second embodiment. FIG. 15 is a diagram showing a change over time in the ratio ((second amount of substance+third amount of substance)/first amount of substance) of the sum of the second amount of substance (Cl_{SGx}) and the third amount of substance (Cl_{PG}) to the first amount of substance (Si_{SGx}) of the process gas supplied to the reactor 10 of the vapor phase growth apparatus 200. (Second amount of substance+third amount of substance)/first amount of substance is controlled by the control circuit 12.

The control circuit 12 controls the ratio ((second amount of substance+third amount of substance)/first amount of substance) of the sum of the second amount of substance (Cl_{SGx}) and the third amount of substance (Cl_{PG}) to the first amount of substance (Si_{SGx}) to be 30 or more in the initial period. (Second amount of substance+third amount of substance)/first amount of substance can be expressed as (Cl_{SGx}+Cl_{PG})/Si_{SGx}.

The control circuit 12 can set (second amount of substance+third amount of substance)/first amount of substance to 30 or more by controlling the flow rate of the mixed source gas SGx and the flow rate of the purge gas PG in consideration of the atomic concentration of silicon and the atomic concentration of chlorine contained in the mixed source gas SGx and the atomic concentration of chlorine contained in the purge gas PG. (Second amount of substance+third amount of substance)/first amount of substance is, for example, 30 or more and 200 or less.

The control circuit 12 controls the flow rates of the mixed source gas SGx and the purge gas PG as shown in FIG. 13, so that (second amount of substance+third amount of substance)/first amount of substance is kept constant in the initial period. In addition, by controlling the flow rates of the mixed source gas SGx and the purge gas PG as shown in FIG. 13, (second amount of substance+third amount of substance)/first amount of substance decreases in the flow rate increase period. In addition, by controlling the flow rates of the first source gas SG1 and the purge gas PG as shown in FIG. 13, (second amount of substance+third amount of substance)/first amount of substance is kept constant in the constant flow rate period.

For example, the control circuit 12 controls the ratio (fourth amount of substance/first amount of substance) of a fourth amount of substance (C_{SG2}), which is the amount of carbon contained in the mixed source gas SGx supplied to the reactor 10 per unit time, to the first amount of substance, to be 1.2 or less. For example, the control circuit 12 controls the flow rates of the silicon source gas and the carbon source gas before mixing using a mass flow controller (not shown).

Next, a vapor phase growth method according to the second embodiment will be described.

In the vapor phase growth method according to the second embodiment, the vapor phase growth apparatus 200 shown in FIG. 12 is used. A case of forming a single crystal SiC film 13 (silicon carbide film) on the surface of the wafer W of single crystal SiC will be described as an example.

The mixed source gas SGx contains silicon, carbon, and chlorine. The purge gas PG contains chlorine and hydrogen.

Hereinafter, a case where the mixed source gas SGx is a mixed gas of silane (SiH₄), propane (C₃H₈), hydrogen chloride (HCl), and hydrogen gas (H₂) and the purge gas PG is a mixed gas of hydrogen chloride (HCl) and hydrogen gas (H₂) will be described as an example.

The atomic concentration of silicon in the mixed source gas SGx, the atomic concentration of carbon in the mixed source gas SGx, the atomic concentration of chlorine in the mixed source gas SGx, and the atomic concentration of chlorine in the purge gas PG are each kept constant.

First, the susceptor 14 on which the wafer W is placed is loaded into the reactor 10. The wafer W is formed of single crystal SiC.

Then, the wafer W is rotated at a rotation speed of 300 rpm or more by the rotation driving mechanism 20. Then, the wafer W is heated by the first heater 22 and the second heater 42.

Then, as shown in FIG. 13, at time to, the supply of the mixed source gas SGx into the reactor 10 is started. The mixed source gas SGx is introduced from the mixed source gas supply pipe 86 into the mixed source gas region 55 and is supplied to the reactor 10 through the gas hole 60x of the rectifying plate 60. The flow rate of the mixed source gas SGx is controlled by the control circuit 12.

In addition, as shown in FIG. 13, at time to, the supply of the purge gas PG into the reactor 10 is started. The purge gas PG is supplied from the purge gas supply pipe 87 to the reactor 10 through the purge gas conduit 75. The flow rate of the purge gas PG is controlled by the control circuit 12.

As shown in FIG. 13, from time t0 to time t1, that is, during the initial period, for example, the flow rate of the mixed source gas SGx is kept constant. In addition, during the initial period, for example, the flow rate of the purge gas PG is kept constant.

As shown in FIG. 14, during the initial period, for example, the first amount of substance (Si_{SGx}) and the second amount of substance (Cl_{SGx}) are kept constant. In addition, as shown in FIG. 14, during the initial period, for example, the third amount of substance (Cl_{PG}) is kept constant.

In addition, as shown in FIG. 15, the mixed source gas SGx and the purge gas PG are supplied to the reactor 10 so that the ratio ((second amount of substance+third amount of substance)/first amount of substance) of the sum of the second amount of substance (Cl_{SGx}) and the third amount of substance (Cl_{PG}) to the first amount of substance (Si_{SGx}) is 30 or more in the initial period. In the initial period, (second amount of substance+third amount of substance)/first amount of substance is constant, for example.

The mixed source gas SGx and the purge gas PG supplied from the gas introduction unit 11 into the reactor 10 form a gas flow toward the surface of the wafer W. Silicon atoms and carbon atoms contained in the mixed source gas SGx react on the surface of the wafer W, forming the single crystal SiC film 13 on the surface of the wafer W.

As shown in FIG. 13, in the flow rate increase period after the initial period, the flow rate of the mixed source gas SGx is increased. In addition, as shown in FIG. 13, in the initial period and the flow rate increase period, for example, the flow rate of the purge gas PG is kept constant.

As shown in FIG. 14, in the flow rate increase period, the first amount of substance (Si_{SGx}) and the second amount of substance (Cl_{SGx}) increase. In addition, as shown in FIG. 14, for example, in the initial period and the flow rate increase period, the third amount of substance (Cl_{PG}) is kept constant.

In the initial period and the flow rate increase period, for example, the ratio (second amount of substance/first amount of substance) of the second amount of substance (Cl_{SGx}) to the first amount of substance (Si_{SGx}) is kept constant.

As shown in FIG. 13, in the constant flow rate period after the flow rate increase period, the flow rate of the mixed source gas SGx and the flow rate of the purge gas PG are kept constant.

In the flow rate increase period and the constant flow rate period, for example, the ratio (fourth amount of substance/first amount of substance) of the fourth amount of substance to the first amount of substance (Si_{SGx}) is 0.1 or more and 1.2 or less.

After the SiC film 13 is formed, the heating by the first heater 22 and the second heater 42 is stopped to lower the temperature of the wafer W. Thereafter, the wafer W is unloaded from the reactor 10 together with the susceptor 14.

According to the vapor phase growth apparatus and the vapor phase growth method according to the second embodiment, in the initial period, the ratio ((second amount of substance+third amount of substance)/first amount of substance) of the sum of the second amount of substance, which is the amount of substance of chlorine contained in the mixed source gas SGx supplied to the reactor 10 per unit time, and the third amount of substance, which is the amount of substance of chlorine contained in the purge gas PG supplied to the reactor 10 per unit time, to the first amount of substance, which is the amount of substance of silicon contained in the mixed source gas SGx supplied to the reactor 10 per unit time, is controlled to be 30 or more. Therefore, similarly to the first embodiment, when forming an SiC film on the surface of a wafer, the occurrence of defects such as pits and bumps on the surface of the SiC film is suppressed.

As described above, according to the second embodiment, it is possible to realize a vapor phase growth apparatus and a vapor phase growth method capable of reducing defects in a film.

Up to now, embodiments have been described with reference to specific examples. Embodiments are merely given as examples, and there is no limitation on embodiments. In addition, the components of embodiments may be combined as appropriate.

In the first and second embodiments, the case of forming a single crystal SiC film has been described as an example. However, embodiments can also be applied to the formation of a polycrystalline or amorphous SiC film.

In addition, in the first and second embodiments, the wafer of single crystal SiC has been described as an example of the substrate. However, the substrate is not limited to the wafer of single crystal SiC.

In addition, in the first and second embodiments, nitrogen has been described as an example of the n-type impurity. However, for example, phosphorus (P) can be applied as the n-type impurity. In addition, p-type impurities can also be applied as impurities.

In addition, in the first and second embodiments, a single wafer type epitaxial growth apparatus that forms a film on a single wafer has been described as an example. However, embodiments can also be applied to a batch type epitaxial growth apparatus that forms films on a plurality of wafers simultaneously.

In addition, in the first embodiment, the case where the atomic concentration of silicon in the first source gas SG1, the atomic concentration of chlorine in the first source gas SG1, the atomic concentration of carbon in the second source gas SG2, and the atomic concentration of chlorine in the purge gas PG are constant has been described as an example. However, it is also possible to change the atomic concentration of silicon in the first source gas SG1, the atomic concentration of chlorine in the first source gas SG1, the atomic concentration of carbon in the second source gas SG2, or the atomic concentration of chlorine in the purge gas PG.

In addition, in the second embodiment, the case where the atomic concentration of silicon in the mixed source gas SGx, the atomic concentration of carbon in the mixed source gas SGx, the atomic concentration of chlorine in the mixed source gas SGx, and the atomic concentration of chlorine in the purge gas PG are constant has been described as an example. However, it is also possible to change the atomic concentration of silicon in the mixed source gas SGx, the atomic concentration of carbon in the mixed source gas SGx, the atomic concentration of chlorine in the mixed source gas SGx, or the atomic concentration of chlorine in the purge gas PG.

In addition, in the first embodiment, the case where the second source gas SG2 is not supplied to the reactor 10 in the initial period has been described as an example. However, it is also possible to supply the second source gas SG2 to the reactor 10 in the initial period.

In addition, in the second embodiment, the case where the carbon source gas is supplied to the reactor 10 in the initial period has been described as an example. However, it is also possible not to supply the carbon source gas to the reactor 10 in the initial period.

In the first and second embodiments, the description of parts that are not directly required for the description of embodiments, such as the apparatus configuration or the manufacturing method, is omitted. However, the required apparatus configuration, manufacturing method, and the like can be appropriately selected and used. In addition, all vapor phase growth apparatuses that include the elements of embodiments and that can be appropriately redesigned by those skilled in the art are included in the scope of embodiments. The scope of embodiments is defined by the scope of claims and the scope of their equivalents.

What is claimed is:

1. A vapor phase growth apparatus, comprising:
a reactor;
a holder provided in the reactor, a substrate being placed on the holder;
a source gas flow path supplying a first source gas containing silicon and chlorine into the reactor;
a purge gas flow path supplying a purge gas containing chlorine and hydrogen into the reactor; and
a control unit controlling supply of the first source gas and the purge gas into the reactor,
wherein the control unit controls a ratio ((second amount of substance+third amount of substance)/first amount of substance) of a sum of a second amount of substance as an amount of substance of chlorine contained in the first source gas supplied to the reactor per unit time and a third amount of substance as an amount of substance of chlorine contained in the purge gas supplied to the reactor per unit time to a first amount of substance as an amount of substance of silicon contained in the first source gas supplied to the reactor per unit time to be 30 or more in a first period, and
the control unit controls a flow rate of the first source gas to increase in a second period after the first period.

2. The vapor phase growth apparatus according to claim 1,
wherein the control unit further controls supply of a second source gas containing carbon into the reactor, and
the control unit controls to start the supply of the second source gas into the reactor after the first period.

3. The vapor phase growth apparatus according to claim 2,
wherein the control unit controls a ratio (fourth amount of substance/first amount of substance) of a fourth amount of substance as an amount of carbon contained in the second source gas supplied to the reactor per unit time to the first amount of substance to be 1.2 or less.

4. The vapor phase growth apparatus according to claim 1,
wherein the control unit controls a ratio (second amount of substance/first amount of substance) of the second amount of substance to the first amount of substance to be constant in the first period and the second period.

5. The vapor phase growth apparatus according to claim 1,
wherein the control unit controls the third amount of substance to be constant in the first period and the second period.

6. A vapor phase growth method for forming a silicon carbide film on a substrate placed on a holder provided in a reactor, comprising:
supplying a first source gas containing silicon and chlorine and a purge gas containing chlorine and hydrogen into the reactor so that a ratio ((second amount of substance+third amount of substance)/first amount of substance) of a sum of a second amount of substance as an amount of substance of chlorine contained in the first source gas supplied to the reactor per unit time and a third amount of substance as an amount of substance of chlorine contained in the purge gas supplied to the reactor per unit time to a first amount of substance as an amount of substance of silicon contained in the first source gas supplied to the reactor per unit time is 30 or more in a first period; and
increasing a flow rate of the first source gas supplied into the reactor in a second period after the first period.

7. The vapor phase growth method according to claim 6,
wherein, after the first period, supply of a second source gas containing carbon into the reactor is started.

8. The vapor phase growth method according to claim 7,
wherein a ratio (fourth amount of substance/first amount of substance) of a fourth amount of substance as an amount of substance of carbon contained in the second source gas supplied to the reactor per unit time to the first amount of substance is 1.2 or less.

9. The vapor phase growth method according to claim 6,
wherein a ratio (second amount of substance/first amount of substance) of the second amount of substance to the first amount of substance is constant in the first period and the second period.

10. The vapor phase growth method according to claim 6,
wherein the third amount of substance is constant in the first period and the second period.
